(19) United States
(12) Patent Application Publication
(10) Pub. No.: US 2015/0015802 A1
(43) Pub. Date: Jan. 15, 2015

(54) TOUCH SENSOR

(71) Applicant: SAMSUNG ELECTRO-MECHANICS CO., LTD., Suwon (KR)

(72) Inventors: Kee Su Jeon, Suwon (KR); Kang Heon Hur, Suwon (KR); Man Sub Shin, Suwon (KR); Jang Ho Park, Suwon (KR); Beom Seok Oh, Suwon (KR)

(73) Assignee: SAMSUNG ELECTRO-MECHANICS CO., LTD., Suwon (KR)

(21) Appl. No.: 14/062,243

(22) Filed: Oct. 24, 2013

(30) Foreign Application Priority Data
Jul. 10, 2013 (KR) 10-2013-0081085

(51) Int. Cl. G06F 3/041; H05K 3/10

(52) U.S. Cl. CPC G06F 3/041; H05K 3/10
USPC 349/12; 29/846

(57) ABSTRACT

Disclosed herein is a touch sensor including: a window substrate; bezels formed along an edge of the window substrate; a first insulating layer stacked while being filled between the bezels to be formed on the window substrate; a second insulating layer applied or adhered onto the bezel and the first insulating layer; and an electrode pattern formed on the second insulating layer.

### CROSS REFERENCE TO RELATED APPLICATION

This application claims the benefit of Korean Patent Application No. 10-2013-0081085, filed on Jul. 10, 2013, entitled “Touch Sensor”, which is hereby incorporated by reference in its entirety into this application.

### BACKGROUND OF THE INVENTION

1. Technical Field

The present invention relates to a touch sensor.

2. Description of the Related Art

In accordance with the growth of computers using a digital technology, devices assisting computers have also been developed, and personal computers, portable transmitters and other personal information processors execute processing of text and graphics using various input devices such as a keyboard and a mouse.

In accordance with the rapid advancement of an information-oriented society, the use of computers has gradually been widened. However, it is difficult to efficiently operate products using only a keyboard and a mouse currently serving as an input device. Therefore, the necessity for a device that is simple, has a less malfunction, and is capable of easily inputting information has increased.

In addition, techniques for input devices have progressed toward techniques related to high reliability, durability, innovation, designing and processing beyond a level of satisfying general functions. To this end, a touch sensor has been developed as an input device capable of inputting information such as text, graphics, or the like.

The touch sensor is mounted on a display surface of an image display device such as an electronic organizer, a flat panel display device including a liquid crystal display (LCD) device, a plasma display panel (PDP), an electroluminescence (EL) element, or the like, or a cathode ray tube (CRT) to allow a user to select desired information while viewing the image display device.

The touch sensor is classified into a resistive type touch sensor, a capacitive type touch sensor, an electromagnetic type touch sensor, a surface acoustic wave (SAW) type touch sensor, and an infrared type touch sensor. These various types of touch sensors are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch sensor and the capacitive type touch sensor have been prominently used in a wide range of fields.

Generally, in these touch sensors, a bezel part covering electrode wirings or provided with decorative patterns and having a color such as a black color, a white color, or the like, is formed in a window glass disposed at the outermost portion of a touch sensor structure.

As a specific example of a touch sensor according to the prior art at which the bezel part is formed, there may be a touch sensor disclosed in Korean Patent Laid-Open Publication No. 2010-0134226.

However, the touch sensor according to the prior art has a problem that a disconnection or a crack occurs in an electrode due to a step of the bezel part or non-uniformity of a surface of the bezel part at the time of forming the electrode at the bezel part.

### PRIOR ART DOCUMENT

### Patent Document

(Patent Document 1) Korean Patent Laid-Open Publication No. 2010-0134226

### SUMMARY OF THE INVENTION

The present invention has been made in an effort to provide a touch sensor capable of decreasing a defective rate by preventing or decreasing a step or non-uniformity of a surface due to a bezel.

According to a preferred embodiment of the present invention, there is provided a touch sensor containing a bezel composite, including: a window substrate; bezels formed along an edge of the window substrate; an insulating layer stacked or adhered while being filled between the bezels to be formed on the window substrate; and an electrode pattern formed on the insulating layer.

The insulating layer may be made of one of an acryl based thin film, a urethane based thin film, a silicone based thin film, a polyester based thin film, a polyamide based thin film, an epoxy based thin film, a vinyl alkyl ether based thin film, an SiOx thin film, and an SiNx thin film.

According to another preferred embodiment of the present invention, there is provided a touch sensor including: a window substrate; bezels formed along an edge of the window substrate; a first insulating layer stacked while being filled between the bezels to be formed on the window substrate; a second insulating layer applied or adhered onto the bezel and the first insulating layer;

and an electrode pattern formed on the second insulating layer.

The first insulating layer may be stacked up to a height (BL) of the bezel.

A height (BL) of the bezel in a stacked direction may satisfy the following Equation: 0 μm<height(BL)≦40 μm.

A height (L) of the first insulating layer in a stacked direction may satisfy the following equation: 0 μm≦height (L) of first insulating layer<height (BL) of bezel×1.3 μm.

A height (d) at a central point of the window substrate may satisfy the following equation: height (2L) of second insulating layer in stacked direction×0.05 μm<height (d) at central point<height (2L) of second insulating layer×1.3 μm.

The height (2L) of the second insulating layer in the stacked direction may not exceed three times of the height (BL) of the bezel.

The first and second insulating layers may be made of the same material.

The first and second insulating layers may be made of one of an acryl based thin film, a urethane based thin film, a silicone based thin film, a polyester based thin film, a polyimide based thin film, an epoxy based thin film, a vinyl alkyl ether based thin film, an SiOx thin film, and an SiNx thin film.

According to still another preferred embodiment of the present invention, there is provided a method of manufacturing a touch sensor including: a) fixing a window substrate having bezels formed along an edge thereof; b) filling a first insulating layer between the bezels on one surface of the window substrate; c) forming a second insulating layer so as to traverse the bezels and the first insulating layer; and d) forming an electrode pattern on the second insulating layer.

In the step b), a height (L) of the first insulating layer formed in a stacked direction may satisfy the following equation: 0≦L<height (BL) of bezel×1.3 μm.

In the step c), a height (d) at a central point of the window substrate may satisfy the following equation: height (2L) of second insulating layer in stacked direction×0.05 μm<d<height (2L) of second insulating layer×1.3 μm.

In the step c), the height (2L) of the second insulating layer in the stacked direction may not exceed three times of the height (BL) of the bezel.

In the step c), the second insulating layer may be formed using the same material as that of the first insulating layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view of a touch sensor according to a preferred embodiment of the present invention;

FIG. 2 is a cross-sectional view of the touch sensor shown in FIG. 1;

FIG. 3 is a cross-sectional view of the touch sensor of FIG. 1 including a first insulating layer;

FIG. 4 is a cross-sectional view of the touch sensor of FIG. 3 including a second insulating layer;

FIGS. 5A to 5D are illustrative views showing a shape generated in a process in a screen printing scheme;

FIG. 6 is an illustrative view of a dry film lamination process;

FIG. 7 is a cross-sectional view of a touch sensor according to a second preferred embodiment of the present invention; and

FIGS. 8A to 8C are views showing a method of manufacturing a touch sensor according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

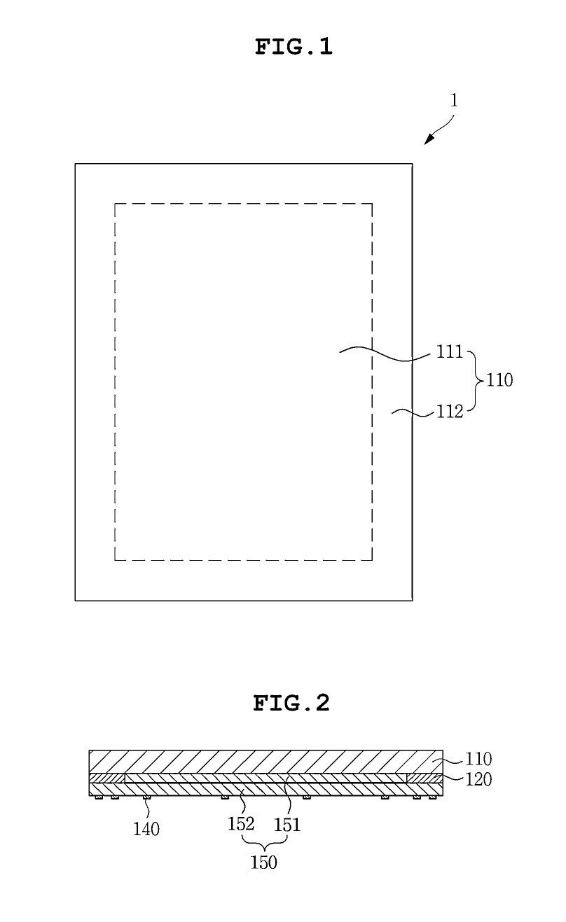

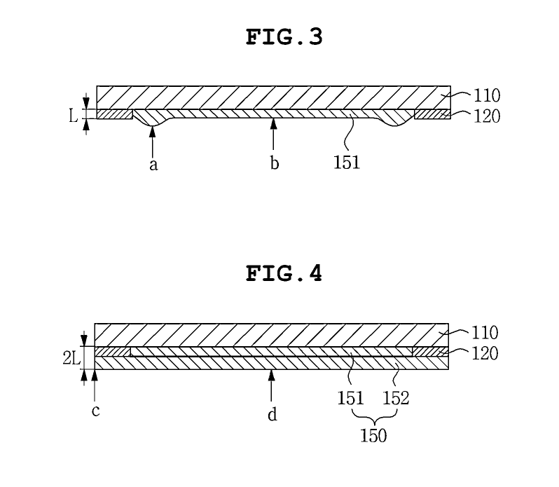

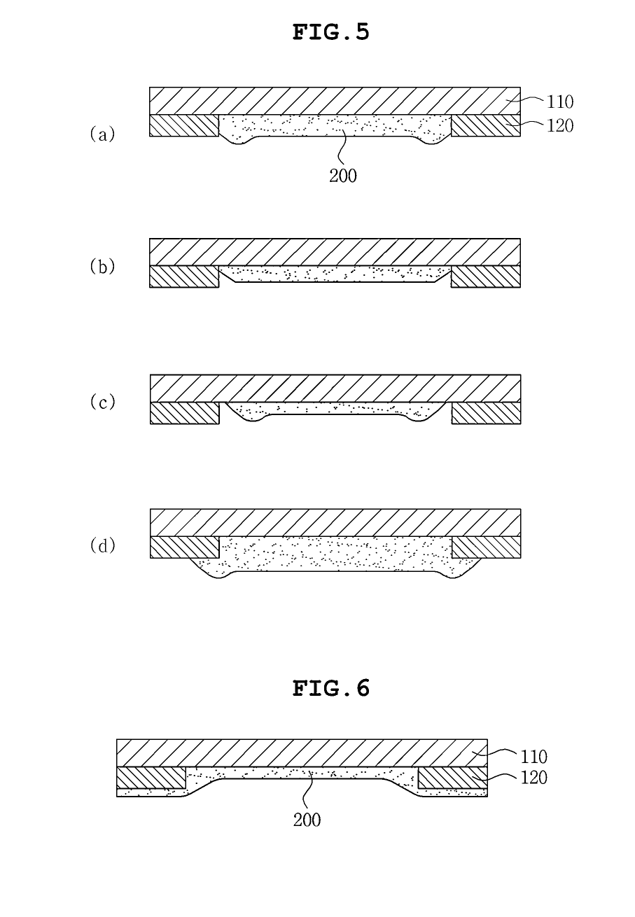

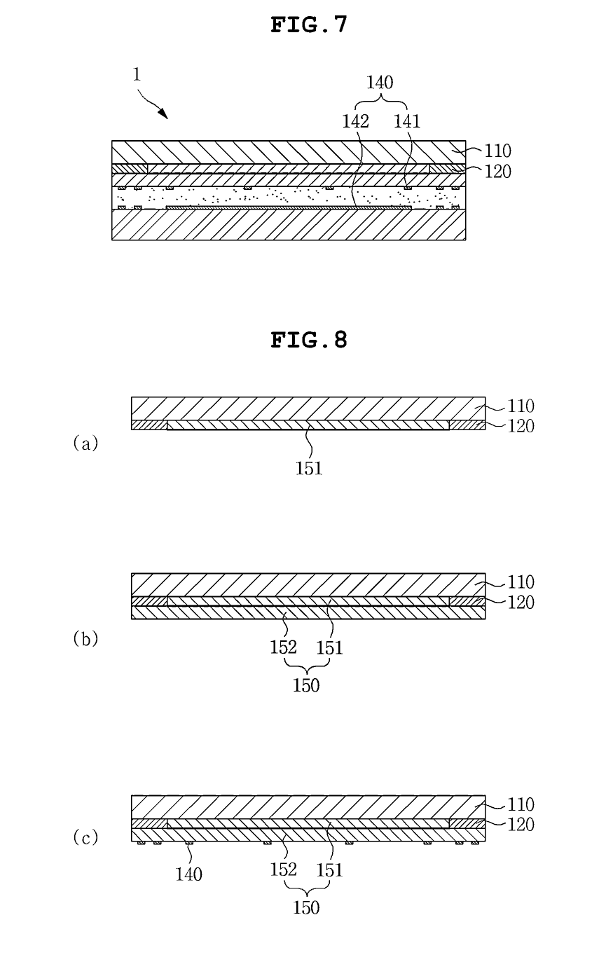

FIG. 1 is a plan view of a touch sensor according to a preferred embodiment of the present invention; FIG. 2 is a cross-sectional view of the touch sensor shown in FIG. 1; FIG. 3 is a cross-sectional view of the touch sensor of FIG. 1 including a first insulating layer; FIG. 4 is a cross-sectional view of the touch sensor of FIG. 3 including a second insulating layer; FIGS. 5A to 5D are illustrative views showing a shape generated in a process in a screen printing scheme; FIG. 6 is an illustrative view of a dry film lamination process; FIG. 7 is a cross-sectional view of a touch sensor according to a second preferred embodiment of the present invention; and FIGS. 8A to 8C are views showing a process of manufacturing a touch sensor according to the preferred embodiment of the present invention.

Referring to FIG. 1, the touch sensor according to the preferred embodiment of the present invention is configured to include a window substrate 110 and bezels 120 disposed at an inactive region of the window substrate 110.

According to the preferred embodiment of the present invention, a step occurring at the time of processing the window substrate 110 and the bezel 120 is removed or minimized to improve reliability of an electrical operation of an electrode pattern 140 formed on an insulating layer 150. In addition, a yield of a processing process is improved to improve productivity of the touch sensor 1.

Referring to FIGS. 1 and 2, the window substrate 110 may serve to provide a region at which the electrode pattern 140 for detecting a touch position is formed. The window substrate 110 should have support force capable of supporting the electrode pattern 140 and transparency so that a user may recognize an image provided by an image display device First and second insulating layers 151 and 152 are sequentially applied and stacked onto the window substrate 110.

The window substrate 110 may be formed at the outermost portion of the touch sensor 1 in a direction in which a touch of the user is input and be made of tempered glass, or the like, having a predetermined strength or more to serve as a protective layer protecting the touch sensor 1. In consideration of the support force and the transparency, the window substrate 110 may be made of a material such as polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), or the like.

Meanwhile, the window substrate 110 may be divided into an active region 111 and an inactive region 112 formed along an edge of the active region 111, as shown in FIG. 1. The active region 111 is a region at which a touch operation is conducted by the user and a screen region at which the user visually confirms an operation scene of a device. In addition, the inactive region 112 is a region covered by a bezel 120 that is formed on the window substrate 110 and is to be described below so as not to be exposed to the outside.

The bezel 120 is formed at the inactive region 112 of the window substrate 110. The bezel 120 is disposed along an edge of the window substrate 110. That is, it is preferable that the bezel 120 is disposed at one side of the inactive region 112 and has a height (BL) of 0 to 40 μm. The height (BL) of the bezel 120 is determined in consideration of visibility of the touch sensor 1 and a thickness of a product.

The bezel 120 serves to cover or decorate one side of wiring electrodes in the inactive region 112 of the window substrate 110. In addition, the decorative pattern such as a logo of a manufacturer may also be formed in the bezel 120 if necessary.

Referring to FIGS. 3 and 4, the insulating layer 150 serves to protect an electrode pattern 140 to be described below. The insulating layer 150 includes first and second insulating layers 151 and 152 that are sequentially stacked. The insulating layer 150 includes the first insulating layer 151 applied up to the height (BL) of the bezel 120 and the second insulating layer 152 applied to a surface of the first insulating layer 151. In some cases, in the case of solving non-uniformity of the surface although a step is allowed to some degree, the application of the first insulating layer may be omitted. In this case, the application of the first insulating layer may be omitted, and the second insulating layer may be adhered or applied in a spin coating or film form. In this case, the insulating layer has a form similar to a form shown in FIG. 6.

The first insulating layer 151 contacts one side of the window substrate 110 and is filled between the bezels 120. Here, it is preferable that the first insulating layer 151 is applied up to the height (BL) of the bezel 120 to a form a horizontal surface. This allows a height (L) of the first insulating layer 151 and the height (BL) of the bezel 120 to be horizontal to each other.

The first insulating layer 151 may be formed using an organic insulating film or an inorganic insulating film by a printing process, a chemical vapor deposition (CVD) process, a sputtering process, a spin coating process, a slot die process, a lamination process, or the like. Here, applying and adhering processes are performed so that the height (L) of the first insulating layer 151 and the height (BL) of the bezel 120 are horizontal to each other. Here, a process tolerance is generated between the height (BL) of the bezel 120 and the height L of the first insulating layer 151.

Phenomena generated in an adhesion process using screen printing and a film as an example of a process will be described with reference to FIGS. 5A to 6, a phenomenon (See FIG. 5A) that an applying solution 200 of the first insulating layer 151 or an adhesive layer is biased toward both sides, a phenomenon (See FIGS. 5B and 5C) that the applying solution 200 of the first insulating layer 151 or the adhesive layer is injected to be less than the height (BL) of the bezel 120, a phenomenon (See FIG. 5D) that the applying solution 200 of the first insulating layer 151 or the adhesive layer is injected to be more than the height (BL) of the bezel 120, a phenomenon (See FIG. 6) that the applying solution 200 of the first insulating layer 151 or the adhesive layer is adhered to the bezel 120 while traversing the bezel 120, and the like, have been generated. These phenomena are generated in a process of filling the first insulating layer 151 between the bezels 120. In addition, in the case in which the above-mentioned phenomena are generated in the first insulating layer 151, a problem that an electrical signal on a wiring electrode 140 to an electrode pattern 140 to be described below is short-circuited has been generated. In addition, a problem that it is difficult to form the electrode pattern to be horizontal to the insulating layer 150 has been generated.

Referring to FIG. 3, the first insulating layer 151 is filled between the bezels 120. Here, the height (L) of the first insulating layer 151 satisfies the following equation: height (L) of first insulating layer 151≦height (BL) of bezel 120×1.3 μm. Here, the height (BL) of the bezel 120 satisfies the following equation: 0 μm<height (BL) of bezel≦40 μm.

A height difference between points a and b of the applying solution of the first insulating layer 151 and the adhesive layer is equal to or less than 35% with respect to a height of a central portion. A processing tolerance of the first insulating layer is within (height at point a-height at point b)/height at point b×100<35%. That is, it may be confirmed that the first insulating layer 151 is not horizontally formed, but has a processing tolerance. It is preferable that one of the thin films such as an acryl based thin film, a urethane based thin film, a silicone based thin film, a polyester based thin film, a polyamide based thin film, an epoxy based thin film, a vinyl alkyl ether based thin film, an SiOx thin film, an SiNx thin film, and the like, is used as a material of the first insulating layer 151.

Referring to FIG. 4, the second insulating layer 152 is formed on surfaces of the first insulating layer 151 and the bezel 120. The second insulating layer 152 is formed to contact the surfaces of the first insulating layer 151 and the bezel 120. The second insulating layer 152 prevents a disconnection of the wiring electrode formed at the inactive region 112 of the bezel 120 to improve electrical reliability. A height of the center d of the second insulating layer 152 satisfies the following equation: height (2L) of second insulating layer×0.05 μm<height of center d<height (2L) of second insulating layer×1.3 μm. It may be confirmed that when the second insulating layer 152 is applied or adhered, a processing tolerance is significantly decreased.

It is preferable that the height (2L) of the second insulating layer 152 satisfies the following equation: 2L(μm)/BL(μm)≦3. That is, it is preferable that the total height including the heights of the first and second insulating layers 151 and 152 and the bezel 120 is set to 120 μm or less.

It is preferable that one of the thin films such as an acryl based thin film, a urethane based thin film, a silicone based thin film, a polyester based thin film, a polyamide based thin film, an epoxy based thin film, a vinyl alkyl ether based thin film, an SiOx thin film, an SiNx thin film, and the like, is used as a material of the second insulating layer 152. This is not to limit a material of the second insulating layer 152. It is preferable that the second insulating layer 152 is made of the same material as that of the first insulating layer 151.

The electrode pattern 140 is formed on the second insulating layer 152. A self capacitive type touch sensor or a mutual capacitive type touch sensor may be manufactured using an electrode pattern 140 having a single layer structure. However, the touch sensor according to the preferred embodiment of the present invention is not limited thereto.

In a touch sensor according to a second preferred embodiment of the present invention, a description of the same components as those of the touch sensor according to the first preferred embodiment of the present invention will be omitted, and a structure of an electrode pattern will be described in detail.

Referring to FIG. 7, the electrode pattern 140 includes a first electrode pattern 141 formed on the second insulating layer 152 and a second electrode pattern 142 spaced apart from the first electrode pattern 141. The electrode pattern 140 includes an adhesive layer formed between the first and second electrode patterns 141 and 142. The adhesive layer serves to dispose the first and second electrode patterns 141 and 142 so as to face each other. Here, a material of the first adhesive layer is not particularly limited, but may be an optical clear adhesive (OCA), a double adhesive tape (DAT), or other transparent insulating materials.

The electrode pattern 140 serves to generate a signal by an input unit of a touch to allow a touch coordinate to be recognized from a controlling unit (not shown). The first and second electrode patterns 141 and 142 may be formed in a direction in which they intersect with each other. For example, when one or more first electrode patterns 141 are formed in an X axis direction so as to be in parallel with each other, one or more second electrode patterns 142 may be formed in a Y axis direction in which they intersect with the first electrode patterns 141 so as to be in parallel with each other. Therefore, a coordinate of a touch point of a user is recognized by the first and second electrode patterns 141 and 142, such that the touch sensor may be driven. In the preferred embodiment of the present invention, a material of the first and second electrode patterns 141 and 142 is not particularly limited as long as it has conductivity.

The electrode pattern 140 may be formed in a mesh pattern using copper (Cu), aluminum (Al), gold (Au), silver (Ag), titanium (Ti), palladium (Pd), chromium (Cr), nickel (Ni), or a combination thereof. Particularly, the mesh pattern may be formed by continuously arranging one or more unit patterns (not shown). Here, the unit pattern may have a rectangular shape, a triangular shape, a diamond shape, or other various shapes.

Meanwhile, the electrode pattern 140 may also be made of metal silver formed by exposing/developing a silver salt emulsion layer, a metal oxide such as an indium thin oxide (ITO), or the like, a conductive polymer such as poly-3, 4-ethylenedioxythiophene/polystyrenesulfonate (PEDOT/PSS), or the like, having excellent flexibility and a simple coating process, in addition to the above-mentioned metal.

FIGS. 8A to 8C are views showing a method of manufacturing a touch sensor according to the preferred embodiment of the present invention.

The method of manufacturing a touch sensor 1 according to the preferred embodiment of the present invention may include a) fixing a window substrate having bezels formed along an edge thereof; b) filling a first insulating layer between the bezels on one surface of the window substrate; c) forming a second insulating layer so as to traverse the bezels and the first insulating layer; and d) forming an electrode pattern on the second insulating layer.

The window substrate 110 is made of a transparent material for visibility of the touch sensor 1 and is made of tempered glass in order to protect internal components from external impact. Since a material of the window substrate 110 has been described with reference to the touch sensor 1 according to the preferred embodiment of the present invention, an overlapped description will be omitted.

FIG. 8A is a view showing a state in which the first insulating layer 151 is applied onto the window substrate 110. The first insulating layer 151 is filled between the bezels 120 by a printing process, a chemical vapor deposition (CVD) process, a sputtering process, a spin coating process, a slot die process, or the like. The filled first insulating layer 151 is made of an organic insulating film or an inorganic insulating film. Here, it is preferable that the first insulating layer 151 is filled up to a height of the bezel 120. However, a process error that an applying solution is filled at a height excessively higher than that of the bezel 120 or at a height lower than that of the bezel 120 in a process in which it is filled between the bezels 120 may frequently occur. In some cases, a process of applying the first insulating layer may be omitted in the range in which the process error does not effect on the subsequent process. In this case, the insulating layer serves to decrease a step or remove non-uniformity of a surface.

A height (L) of the first insulating layer 151 is determined in consideration of visibility, a thickness, and a yield of a product Therefore, the first insulating layer 151 is filled in the range of 0≦L<height (BL) of bezel×1.3 μm. It is preferable that a screen printing process is used as the process of stacking the first insulating layer 151. As the process of stacking the first insulating layer 151, the process such as the screen printing process, the lamination process, the sputtering process, the slot die process, or the like, may also be used as described above.

FIG. 8B is a view showing a state in which the second insulating layer 152 is applied onto the window substrate 110. The second insulating layer 152 is formed on surfaces of the first insulating layer 151 and the bezel The second insulating layer 152 is stacked using a material and a process that are the same as those of the first insulating layer 151. However, in some cases, the second insulating layer 152 is stacked using a material and a process that are different from those of the first insulating layer 151.

When the second insulating layer 152 is formed on the first insulating layer 151, a height d at a central point of the window substrate 110 satisfies the following Equation: height (2L) of second insulation layer in stacked direction×0.05 μm<height d at central point≦height (2L) of second insulating layer×1.3 μm. This range is set in order to decrease electrical reliability of the electrode pattern 140 at the time of forming the electrode pattern 140. The height (2L) of the second insulating layer 152 in a stacked direction does not exceed three times of the height (BL) of the bezel 120. This is to prevent an increase in a thickness of a product and improve a yield of the touch sensor 1.

FIG. 8C is a view showing a shape in which the electrode pattern 140 is formed on the window substrate 110. Since a material of the electrode pattern has been described with reference to the touch sensor 1 according to the preferred embodiment of the present invention, an overlapped description will be omitted. The electrode pattern is formed on a surface of the insulating layer. A self capacitive type touch sensor or a mutual capacitive type touch sensor may be manufactured using an electrode pattern 140 having a single layer structure. In addition, a wiring electrode transferring an electrical signal to the outside is formed in the inactive region of the bezel 120.

According to the preferred embodiments of the present invention, the insulating layer is formed to remove or decrease a step or non-uniformity of a surface generated in an applying process, thereby making it possible to decrease a defective rate.

In addition, the insulating layer is formed, thereby making it possible to prevent a disconnection and a malfunction of the electrode.

Further, a flat insulating layer is formed, thereby making it possible to easily form the electrode on the surface of the insulating layer.

Moreover, the insulating layer is formed, thereby making it possible to provide a touch sensor in which electrical conduction of the electrode is improved.

Furthermore, the insulating layer is formed, thereby making it possible to provide a touch sensor in which reliability of the electrode is improved.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch sensor comprising:
a window substrate;
bezels formed along an edge of the window substrate;
an insulating layer stacked or adhered while being filled between the bezels to be formed on the window substrate; and
an electrode pattern formed on the insulating layer.

2. The touch sensor as set forth in claim 1, wherein the insulating layer is made of one of an acryl based thin film, a urethane based thin film, a silicone based thin film, a polyester based thin film, a polyamide based thin film, an epoxy based thin film, a vinyl alkyl ether based thin film, an SiOx thin film, and an SiNx thin film.

3. A touch sensor comprising:
a window substrate;
bezels formed along an edge of the window substrate;
a first insulating layer stacked while being filled between the bezels to be formed on the window substrate;
a second insulating layer applied or adhered onto the bezel and the first insulating layer; and
an electrode pattern formed on the second insulating layer.

4. The touch sensor as set forth in claim 3, wherein the first insulating layer is stacked up to a height (BL) of the bezel.

5. The touch sensor as set forth in claim 3, wherein a height (BL) of the bezel in a stacked direction satisfies the following Equation: 0 μm<height(BL)≦40 μm.

6. The touch sensor as set forth in claim 3, wherein a height (L) of the first insulating layer in a stacked direction satisfies the following equation: height (L) of first insulating layer<height (BL) of bezel×1.3 μm.

7. The touch sensor as set forth in claim 6, wherein a height (d) at a central point of the window substrate satisfies the following equation: height (2L) of second insulating layer in stacked direction×0.05 μm<height (d) at central point<height (2L) of second insulating layer×1.3 μm.

8. The touch sensor as set forth in claim 6, wherein the height (2L) of the second insulating layer in the stacked direction does not exceed three times of the height (BL) of the bezel.

9. The touch sensor as set forth in claim 6, wherein the first and second insulating layers are made of the same material.

10. The touch sensor as set forth in claim 9, wherein the first and second insulating layers are made of one of an acryl based thin film, a urethane based thin film, a silicone based thin film, a polyester based thin film, a polyamide based thin film, an epoxy based thin film, a vinyl alkyl ether based thin film, an SiOx thin film, and an SiNx thin film.

11. A method of manufacturing a touch sensor comprising:
a) fixing a window substrate having bezels formed along an edge thereof;
b) filling a first insulating layer between the bezels on one surface of the window substrate;
c) forming a second insulating layer so as to traverse the bezels and the first insulating layer; and
d) forming an electrode pattern on the second insulating layer.

12. The method as set forth in claim 11, wherein in the step b), a height (L) of the first insulating layer formed in a stacked direction satisfies the following equation: L≦height (BL) of bezel×1.3 μm.

13. The method as set forth in claim 12, wherein in the step c), a height (d) at a central point of the window substrate satisfies the following equation: height (2L) of second insulating layer in stacked direction×0.05 μm<d<height (2L) of second insulating layer×1.3 μm.

14. The method as set forth in claim 12, wherein in the step c), the height (2L) of the second insulating layer in the stacked direction does not exceed three times of the height (BL) of the bezel.

15. The method as set forth in claim 14, wherein in the step c), the second insulating layer is formed using the same material as that of the first insulating layer.
